(19) United States
(12) Patent Application Publication
(10) Pub. No.: US 2024/0124775 A1
(43) Pub. Date: Apr. 18, 2024

(54) SILICON ETCHING LIQUID, AND METHOD FOR PRODUCING SILICON DEVICES AND METHOD FOR PROCESSING SUBSTRATES, EACH USING SAID ETCHING LIQUID

(71) Applicant: TOKUYAMA CORPORATION, Yamaguchi (JP)

(72) Inventors: Yoshiki SEIKE, Yamaguchi (JP); Manami OSHIO, Yamaguchi (JP); Seiji TONO, Yamaguchi (JP)

(73) Assignee: TOKUYAMA CORPORATION, Yamaguchi (JP)

(21) Appl. No.: 18/268,794

(22) PCT Filed: Dec. 22, 2021
(86) PCT No.: PCT/JP2021/047675

§ 371 Date: Jun. 21, 2023

(30) Foreign Application Priority Data
Dec. 24, 2020 (JP) 2020-215648

(51) Int. Cl. C09K 13/00; H01L 21/306

(52) U.S. Cl. CPC C09K 13/00; H01L 21/30608

(57) ABSTRACT

A silicon etching solution contains: a quaternary ammonium hydroxide represented by the following Formula (1): R¹¹R¹²R¹³R¹⁴N⁺·OH⁻ (1) (in the formula, R¹¹, R¹², R¹³, and R¹⁴ are each independently an aryl group, a benzyl group, or an alkyl group having 1 to 4 carbon atoms, and the alkyl group, the aryl group, or the benzyl group may have a hydroxy group); a quaternary ammonium salt represented by the following Formula (2) and having 11 to 20 carbon atoms in total: R²¹R²²R²³R²⁴N⁺·X⁻ (2) (in the formula, one of R²¹, R²², R²³, and R²⁴ is an alkyl group having 16 or less carbon atoms, which may have a substituent, each of the remaining three is an alkyl group having 1 or 2 carbon atoms, the alkyl group having 16 or less carbon atoms and the alkyl group having 1 or 2 carbon atoms may have a hydroxy group, and X is at least one selected from the group consisting of BF₄, a fluorine atom, a chlorine atom, and a bromine atom); a polyhydroxy compound having 2 to 12 carbon atoms and having two or more hydroxy groups in a molecule; and water.

### TECHNICAL FIELD

The present invention relates to a silicon etching solution used in surface processing and an etching step when manufacturing various silicon devices. The present invention also relates to a substrate treatment method using the etching solution. Examples of the substrate include a semiconductor wafer or a silicon substrate. The present invention further relates to a method for manufacturing a silicon device using the etching solution.

### BACKGROUND ART

In a process for manufacturing a semiconductor device, silicon etching is used in various steps. In recent years, as lamination of a memory cell and manufacturing of a logic device become three-dimensional, a processing process of silicon etching is important, and for silicon etching used at this time, demands for smoothness after etching, etching accuracy, etching selectivity for other materials, and the like are becoming stricter due to device densification. In addition, such silicon etching is also applied to processes such as wafer thinning. Such various silicon devices are required to be highly integrated, miniaturized, highly sensitive, and highly functional depending on applications thereof, and in order to satisfy these requirements, the silicon etching is considered important as a fine processing technique in manufacturing of these silicon devices.

Here, examples of the silicon etching include etching using a fluoric acid-nitric acid aqueous solution and etching using an alkali. The former etching using a fluoric acid-nitric acid aqueous solution can be performed isotropically regardless of a crystal orientation of silicon, and can uniformly etch single crystal silicon, polysilicon, and amorphous silicon. However, the fluoric acid-nitric acid aqueous solution oxidizes silicon and etches silicon as a silicon oxide film, and thus has no selection ratio to the silicon oxide film. Therefore, the fluoric acid-nitric acid aqueous solution cannot be used in a semiconductor manufacturing process or the like in which a silicon oxide film remains as a mask material and part of a pattern structure.

Then, in a case of the silicon etching using an alkali, unlike the etching using a fluoric acid-nitric acid aqueous solution, crystal anisotropy is exhibited. The crystal anisotropy means a property (etching anisotropy) that an etching rate differs depending on a crystal orientation of silicon. Utilizing this property, alkaline etching is used for manufacturing a silicon device having a complicated three-dimensional structure from single crystal silicon and for smoothly etching a silicon surface. The alkali has a feature that it not only has a high etching selectivity of silicon compared to a silicon nitride film, but also has a high etching selectivity of silicon compared to a silicon oxide film, and thus can also be used in a semiconductor manufacturing process in which a silicon nitride film and a silicon oxide film remain. Here, a high etching selectivity of silicon means a property that exhibits a particularly high etching property of silicon compared to other member. For example, when etching a substrate having a silicon film of single crystal silicon, polysilicon, or amorphous silicon, and another film (for example, a silicon oxide film), in a case of only etching the silicon film and not etching the silicon oxide film, an etching selectivity of silicon for the silicon oxide film is high. An alkaline etching solution has a high etching selectivity of silicon for the silicon oxide film and the silicon nitride film, and selectively etches the silicon film.

As the alkaline etching solution described above, an aqueous solution of a general alkaline chemical such as KOH, hydrazine, or tetramethylammonium hydroxide (hereinafter also referred to as TMAH) can be used (see Patent Literatures 1 and 2). Among these, KOH and TMAH, which have low toxicity and are easy to handle, are suitably used alone. Among these, TMAH is more suitably used in consideration of low contamination of metal impurities and desirable etching selectivity for the silicon oxide film.

These alkaline etching solutions have such advantages, but also have a problem of a low etching rate at a 111 face of silicon, occasional generation of pyramid-shaped hillocks surrounded by the 111 face, a reduction in smoothness during silicon etching, or generation of etching residues. Although the above problem can be solved by increasing an alkali concentration, in consideration of cost, safety, and ease of waste liquid treatment, it is preferable to reduce the alkali concentration in a silicon etching solution. However, when the alkali concentration is set to a low concentration side, the pyramid-shaped hillocks surrounded by the 111 face are likely to be generated, and as a result, the smoothness after etching is reduced and the etched surface tends to be rough. Therefore, there is a demand for a silicon etching solution that can prevent the generation of the hillocks on the silicon surface and has a high etching selection ratio to a silicon oxide film even when the alkali concentration is on the low concentration side. Here, the etching selection ratio to a silicon oxide film represents a value obtained by dividing an etching rate for silicon by an etching rate for the silicon oxide film.

Regarding the silicon etching using an alkali, Patent Literature 1 discloses an etching solution for a solar cell silicon substrate, which contains an alkali hydroxide, water, and a polyalkylene oxide alkyl ether. Patent Literature 2 discloses an etching solution for a solar cell silicon substrate, which contains an alkaline compound, an organic solvent, a surfactant, and water. In Patent Literature 2, TMAH is exemplified as the alkaline compound, and a polyalkylene oxide alkyl ether is exemplified as the organic solvent, but the alkaline compound actually used is sodium hydroxide or potassium hydroxide. Patent Literature 3 discloses, as an etching solution suitable for selectively removing silicon with respect to silicon-germanium from a microelectronic device containing silicon and silicon-germanium, a silicon etching solution containing water, a quaternary alkyl ammonium hydroxide, and a water-miscible solvent, and describes ethylene glycol, tripropylene glycol methyl ether, or the like, as the water-miscible solvent.

Non-Patent Literature 1 describes a method by which silicon can be etched isotropically by oxidizing a silicon surface by applying a voltage and dissolving an oxide film of the silicon surface with a KOH aqueous solution.

### CITATION LIST

### Patent Literature

Patent Literature 1: Japanese Patent Laid-Open No. 2010-141139
Patent Literature 2: Japanese Patent Laid-Open No. 2012-227304
Patent Literature 3: Japanese Patent Laid-Open No. 2019-050364 (US2019/0085240)
Patent Literature 4: Japanese Patent Laid-Open No. 2012-199521 (US2014/001145)
Patent Literature 5: Japanese Patent Laid-Open No. 2013-135081
Patent Literature 6: Japanese Patent Laid-Open No. 2016-127293 (US2016/186058)
Patent Literature 7: International Publication No. WO 2017/169834 (US2019/025702)

### Non-Patent Literature

Non-Patent Literature 1: Denso Technical Review, Yamashita, et al., 2001, Vol. 6, No. 2, p. 94-99

### SUMMARY OF INVENTION

### Technical Problem

In the etching solutions in Patent Literature 1 and Patent Literature 2, NaOH and KOH are used as the alkaline compound. As described above, the etching using an alkali has a higher selectivity for the silicon oxide film than the fluoric acid-nitric acid aqueous solution, but an alkali metal hydroxide has a higher etching rate for the silicon oxide film than a quaternary ammonium hydroxide. Therefore, the silicon oxide film that should remain as a mask material and part of a pattern structure is also etched, and it is impossible to selectively etch only a silicon film. Further, objects of these etching solutions are to enhance crystal anisotropy and roughen a surface, and therefore, the silicon film cannot be etched smoothly. The etching solution described in Patent Literature 3 is a chemical solution that can selectively remove silicon from silicon-germanium, there is no description about etching silicon smoothly, and an etching rate ratio (100/111) between a (100) face and a (111) face of silicon, which is an index of the described isotropy, is not a sufficient value. Next, in Non-Patent Literature 1, although silicon can be etched isotropically, silicon is not directly dissolved, but is dissolved by etching, with the KOH aqueous solution, the oxide film obtained by the oxidization by applying a voltage, so that there is no etching selection ratio of silicon to the silicon oxide film.

Therefore, an object of the present invention is to provide a silicon etching solution that enables a treatment for preventing generation of hillocks on a silicon surface and has a high selection ratio of silicon compared to silicon oxide film even when an alkali concentration is on a low concentration side.

### Solution to Problem

As a result of diligent efforts, the present inventors have found that the problem described above can be solved by using a silicon etching solution containing a quaternary ammonium hydroxide represented by Formula (1), a quaternary ammonium salt represented by Formula (2), a polyhydroxy compound having 2 to 12 carbon atoms and having two or more hydroxy groups in a molecule, and water. That is, the present invention provides the following silicon etching solution and method for using the same.

[1] A silicon etching solution containing:
a quaternary ammonium hydroxide represented by the following Formula (1):

R¹¹R¹²R¹³R¹⁴N⁺·OH⁻ (1)
(in the formula, R¹¹, R¹², R¹³, and R¹⁴ are each independently an aryl group, a benzyl group, or an alkyl group having 1 to 4 carbon atoms, and the alkyl group, the aryl group, or the benzyl group may have a hydroxy group);
a quaternary ammonium salt represented by the following Formula (2) and having 11 to 20 carbon atoms in total:

R²¹R²²R²³R²⁴N⁺·X⁻ (2)
(in the formula, one of R²¹, R²², R²³, and R²⁴ is an alkyl group having 16 or less carbon atoms, which may have a substituent, each of the remaining three is an alkyl group having 1 or 2 carbon atoms, the alkyl group having 16 or less carbon atoms and the alkyl group having 1 or 2 carbon atoms may have a hydroxy group, and X is at least one selected from the group consisting of BF₄, a fluorine atom, a chlorine atom, and a bromine atom);
a polyhydroxy compound having 2 to 12 carbon atoms and having two or more hydroxy groups in a molecule; and
water, in which
a concentration of the quaternary ammonium salt represented by the Formula (2) is 1.5 mass % to 50 mass %.

[2] The silicon etching solution according to [1], in which
a concentration of the quaternary ammonium hydroxide represented by the Formula (1) is 0.05 mol/L to 1.1 mol/L, and
a concentration of the polyhydroxy compound having 2 to 12 carbon atoms and having two or more hydroxy groups in a molecule is 10 mass % to 80 mass %.

[3] A silicon etching solution containing:
a quaternary ammonium cation represented by the following Formula (1′):

R¹¹R¹²R¹³R¹⁴N⁺ (1′)
(in the formula, R¹¹, R¹², R¹³, and R¹⁴ are each independently an aryl group, a benzyl group, or an alkyl group having 1 to 4 carbon atoms, and the alkyl group, the aryl group, or the benzyl group may have a hydroxy group);
a quaternary ammonium cation represented by the following Formula (2′) and having 11 to 20 carbon atoms in total:

R²¹R²²R²³R²⁴N⁺ (2′)
(in the formula, one of R²¹, R²², R²³, and R²⁴ is an alkyl group having 16 or less carbon atoms, which may have a substituent, each of the remaining three is an alkyl group having 1 or 2 carbon atoms, and the alkyl group having 16 or less carbon atoms and the alkyl group having 1 or 2 carbon atoms may have a hydroxy group); OH⁻;
at least one anion selected from the group consisting of BF₄⁻, F⁻, Cl⁻, and Br⁻;
a polyhydroxy compound having 2 to 12 carbon atoms and having two or more hydroxy groups in a molecule; and
water, in which
a content of the quaternary ammonium cation represented by the Formula (2′) is 0.05 mol/L to 1.31 mol/L, and the silicon etching solution is alkaline.

[4] The silicon etching solution according to [3], in which
a concentration of the quaternary ammonium cation represented by the Formula (1′) is 0.05 mol/L to 1.1 mol/L,
a concentration of OH⁻ is 0.05 mol/L to 1.1 mol/L,
a concentration of the at least one anion selected from the group consisting of BF₄⁻, F⁻, Cl⁻, and Br⁻ is 0.05 mol/L to 1.31 mol/L, and
a concentration of the polyhydroxy compound having 2 to 12 carbon atoms and having two or more hydroxy groups in a molecule is 10 mass % to 80 mass %.

[5] A silicon wafer and/or substrate treatment method, including: etching a silicon wafer or etching a substrate including at least one selected from the group consisting of a silicon single crystal film, a polysilicon film, and an amorphous silicon film by using the silicon etching solution according to any one of [1] to [4].

[6] A method for manufacturing a silicon device, including: a step of etching at least one selected from the group consisting of a silicon wafer, a silicon single crystal film, a polysilicon film, and an amorphous silicon film, in which the etching is performed using the silicon etching solution according to any one of [1] to [4].

### Advantageous Effects of Invention

The silicon etching solution according to the present invention enables a silicon etching treatment in which a surface of a silicon wafer, a single crystal silicon film, a polysilicon film, and an amorphous silicon film can be etched smoothly and a selection ratio silicon compared to a silicon oxide film is high even when a concentration of a quaternary ammonium hydroxide is on a low concentration side.

In particular, in the etching treatment for the silicon wafer, generation of pyramid-shaped hillocks surrounded by a 111 face is prevented, and a silicon surface is free from roughness. In addition, since the treatment can be performed when the concentration of the quaternary ammonium hydroxide is on the low concentration side, toxicity and cost of a waste liquid treatment can be reduced. Therefore, the silicon etching solution according to the present invention is particularly useful as a silicon etching solution for etching a silicon surface smoothly.

### DESCRIPTION OF EMBODIMENTS

(Silicon Etching Solution According to First Embodiment)

A silicon etching solution according to a first embodiment of the present invention contains a quaternary ammonium hydroxide represented by Formula (1), a quaternary ammonium salt represented by Formula (2), a polyhydroxy compound having 2 to 12 carbon atoms and having two or more hydroxy groups in a molecule, and water.

R¹¹R¹²R¹³R¹⁴N⁺·OH⁻ (1)

R²¹R²²R²³R²⁴N⁺·X⁻ (2)

In the quaternary ammonium hydroxide represented by the Formula (1) described above, R¹¹, R¹², R¹³, and R¹⁴ are each independently an aryl group, a benzyl group, or an alkyl group having 1 to 4 carbon atoms, and the alkyl group, the aryl group, or the benzyl group may have a hydroxy group.

The alkyl group for R¹¹, R¹², R¹³, and R¹⁴ has 1 to 4 carbon atoms, and is preferably an alkyl group having 1 or 2 carbon atoms. The aryl group is preferably an aryl group having 6 to 10 carbon atoms.

Preferable examples of each of R¹¹, R¹², R¹³, and R¹⁴ include: an unsubstituted alkyl group having 1 to 4 carbon atoms, such as a methyl group, an ethyl group, an n-propyl group, an i-propyl group, an n-butyl group, an i-butyl group, a sec-butyl group, and a tert-butyl group; a hydroxy group-substituted alkyl group having 1 to 4 carbon atoms, such as a hydroxymethyl group, a hydroxyethyl group, a hydroxy-n-propyl group, a hydroxy-i-propyl group, a hydroxy-n-butyl group, a hydroxy-i-butyl group, a hydroxy-sec-butyl group, and a hydroxy-tert-butyl group; a phenyl group; and a benzyl group.

The total number of carbon atoms in R¹¹, R¹², R¹³, and R¹⁴ is preferably 20 or less, more preferably 16 or less, and particularly preferably 8 or less, from a viewpoint of solubility. Each of R¹¹, R¹², R¹³, and R¹⁴ is preferably an alkyl group having 1 to 4 carbon atoms or a hydroxy group-substituted alkyl group having 1 to 4 carbon atoms, and at least three of R¹¹, R¹², R¹³, and R¹⁴ are preferably the same alkyl group. The alkyl group having 1 to 4 carbon atoms is preferably methyl group, ethyl group, propyl group, a butyl group, or an isobutyl group, the hydroxy group-substituted alkyl group having 1 to 4 carbon atoms is preferably a hydroxyethyl group, and the alkyl group being the same for at least three of R¹¹, R¹², R¹³, and R¹⁴ is preferably a methyl group, an ethyl group, or a butyl group.

Examples of the quaternary ammonium hydroxide represented by the Formula (1) include tetramethylammonium hydroxide (TMAH), tetraethylammonium hydroxide (TEAH), ethyltrimethylammonium hydroxide (ETMAH), tetrapropylammonium hydroxide (TPAH), tetrabutylammonium hydroxide (TBAH), trimethyl-2-hydroxyethylammonium hydroxide (choline hydroxide), dimethylbis(2-hydroxyethyl)ammonium hydroxide, and methyltris(2-hydroxyethyl)ammonium hydroxide. Among these, TMAH, choline hydroxide, TEAH, ETMAH, TPAH, or TBAH those conventionally used in a silicon etching solution including a quaternary ammonium hydroxide can be preferably used. In particular, TMAH, ETMAH, TEAH, or TPAH is most suitably used because of having a high etching rate for silicon. Regarding the quaternary ammonium hydroxide represented by the Formula (1), one may be used alone, or a plurality of different types thereof may be used in combination.

A concentration of the quaternary ammonium hydroxide represented by the Formula (1) is also not particularly different from that of a conventionally known silicon etching solution, and the concentration is preferably in a range of 0.05 mol/L to 1.1 mol/L since a uniform etching solution having high solubility can be obtained and an excellent etching effect can be obtained. The concentration of the quaternary ammonium hydroxide is more preferably in a range of 0.05 mol/L to 0.6 mol/L. The etching solution according to the present invention enables smooth etching with a high selectivity even when the concentration of the quaternary ammonium hydroxide is in a low range.

The silicon etching solution according to the present invention further contains the quaternary ammonium salt represented by the Formula (2) described above. By containing the quaternary ammonium salt represented by the Formula (2), generation of pyramid-shaped hillocks surrounded by a (111) face on a silicon surface can be further prevented, and the silicon surface can be etched more smoothly without any roughness. Therefore, even when a concentration of the polyhydroxy compound is low, the generation of the pyramid-shaped hillocks surrounded by the (111) face on the silicon surface can be prevented, and the silicon surface can be etched smoothly without any roughness.

In the quaternary ammonium salt represented by the Formula (2), one of R²¹, R²², R²³, and R²⁴ is an alkyl group having 16 or less carbon atoms, which may have a substituent, each of the remaining three is an alkyl group having 1 or 2 carbon atoms, and the three alkyl groups may be the same group or different groups. The total number of carbon atoms in a molecule of the quaternary ammonium salt represented by the Formula (2) is 11 to 20. X is at least one selected from the group consisting of BF₄, a fluorine atom, a chlorine atom, and a bromine atom.

The alkyl groups having 16 or less carbon atoms may have a hydroxy group as a substituent. The alkyl group having 1 or 2 carbon atoms may have a hydroxy group as a substituent.

Examples of the alkyl group having 16 or less carbon atoms include: an unsubstituted alkyl group having 16 or less carbon atoms, such as a hexyl group, an octyl group, a decyl group, a dodecyl group, a tetradecyl group, and a hexadecyl group; and a hydroxy group-substituted alkyl group having 16 or less carbon atoms, such as a hydroxyhexyl group, a hydroxyoctyl group, a hydroxydecyl group, a hydroxydodecyl group, a hydroxytetradecyl group, and hexadecyl group. Among these, an alkyl group having 5 or more carbon atoms is preferable, an alkyl group having 8 or more carbon atoms is more preferable, and an alkyl group having 10 or more carbon atoms is particularly preferable. An upper limit of carbon atoms is more preferably 12 or less. The quaternary ammonium salt represented by the Formula (2) contains, as one of R²¹, R²², R²³, and R²⁴, an alkyl group having a relatively large number of carbon atoms as described above.

Three of R²¹, R²², R²³, and R²⁴ are each an alkyl group having 1 or 2 carbon atoms, which may have a hydroxy group, and specific examples thereof include a methyl group, an ethyl group, a hydroxymethyl group, and a hydroxyethyl group. Among these, an alkyl group having 1 or 2 carbon atoms is preferable, and a methyl group is more preferable. The three alkyl groups may be the same group or different groups, and all the three alkyl groups are more preferably methyl groups.

The total number of carbon atoms in a molecule of the quaternary ammonium salt represented by the Formula (2) is 11 to 20, and is more preferably 11 to 15 from viewpoints of water solubility and smooth etching of the silicon surface.

X is BF₄, a fluorine atom, a chlorine atom, or a bromine atom, preferably a chlorine atom or a bromine atom, and more preferably a bromine atom.

Specific examples of the quaternary ammonium salt represented by the Formula (2) particularly suitably used in the present invention preferably include a pentyltriethylammonium salt, a hexyltriethylammonium salt, an octyltrimethylammonium salt, a decyltrimethylammonium salt, a dodecyltrimethylammonium salt, and a tetradecyltrimethylammonium salt. Among these, an octyltrimethylammonium salt, a decyltrimethylammonium salt, or a dodecyltrimethylammonium salt can be preferably used. Regarding the quaternary ammonium salt represented by the Formula (2), one may be used alone, or a plurality of different types thereof may be used in combination. Therefore, X may be two or more types. For example, a mixture of quaternary ammonium salts of the same quaternary ammonium cation and two or more types of X⁻ as counter anions may be used.

A concentration of the quaternary ammonium salt represented by the Formula (2) is 1.5 mass % to 50 mass %, and preferably 1.5 mass % to 25 mass %. An upper limit may be 10 mass % or less. By setting the concentration of the quaternary ammonium salt represented by the Formula (2) in this range, even when the concentration of the quaternary ammonium hydroxide represented by the Formula (1) is low, the silicon surface can be etched smoothly without any roughness. Specifically, surface roughness of a (100) face of silicon is reduced, and the pyramid-shaped hillocks surrounded by the (111) face are prevented, thereby enabling smooth etching.

In addition to the quaternary ammonium hydroxide represented by the Formula (1) and the quaternary ammonium salt represented by the Formula (2), the silicon etching solution according to the present invention further contains a polyhydroxy compound having 2 to 12 carbon atoms and having two or more hydroxy groups in a molecule (hereinafter, simply referred to as “polyhydroxy compound”). By containing the polyhydroxy compound, the generation of the pyramid-shaped hillocks surrounded by the (111) face on the silicon surface can be prevented, and the silicon surface can be etched smoothly without any roughness.

In the polyhydroxy compound, the number of carbon atoms is 2 to 12, and preferably 2 to 6.

A ratio (OH/C) of the number of hydroxy groups to the number of carbon atoms in a molecule of the polyhydroxy compound is preferably 0.3 or more and 1.0 or less, more preferably 0.4 or more and 1.0 or less, and still more preferably 0.5 or more and 1.0 or less, from viewpoints that hydration due to hydrogen bonding between the hydroxy groups and water progresses and the number of free water molecules that contributes to the reaction is reduced to smoothly etch the silicon.

Specific examples of the polyhydroxy compound suitably used in the present invention include ethylene glycol, propylene glycol, 1,3-propanediol, 1,2-butanediol, 1,3-butanediol, 1,4-butanediol, 1,5-pentanediol, 1,2-hexanediol, 1,6-hexanediol, hexylene glycol, cyclohexanediol, pinacol, glycerin, trimethylolpropane, erythritol, pentaerythritol, dipentaerythritol, xylitol, dulcitol, mannitol, and diglycerin. Among these, ethylene glycol, propylene glycol, 1,3-propanediol, 1,2-butanediol, 1,3-butanediol, 1,4-butanediol, glycerin, trimethylolpropane, erythritol, pentaerythritol, dipentaerythritol, xylitol, dulcitol, mannitol, or diglycerin is preferable, and ethylene glycol, glycerin, xylitol, or diglycerin is particularly preferable.

A higher concentration of the polyhydroxy compound indicates that the generation of the pyramid-shaped hillocks surrounded by the (111) face of the silicon surface can be further prevented, and the silicon surface can be etched more smoothly without any roughness. The concentration of the polyhydroxy compound is preferably 10 mass % or more and 80 mass % or less, more preferably 20 mass % or more and 80 mass % or less, and particularly preferably 20 mass % or more and 60 mass % or less, based on a total mass of the etching solution.

Regarding the polyhydroxy compound, one may be used alone, or a plurality of different types thereof may be used in combination.

In addition to the quaternary ammonium hydroxide represented by the Formula (1), the quaternary ammonium salt represented by the Formula (2), the polyhydroxy compound, and water, a surfactant and the like may be added to the silicon etching solution according to the present invention as long as the object of the present invention is not impaired. However, the preferred silicon etching solution consists essentially of the quaternary ammonium hydroxide represented by the Formula (1), the quaternary ammonium salt represented by the Formula (2), the polyhydroxy compound, and water, and a content of other components such as a surfactant is preferably 1 mass % or less, and such other components are more preferably not contained. That is, all of the balance other than the quaternary ammonium hydroxide represented by the Formula (1), the quaternary ammonium salt represented by the Formula (2), and the polyhydroxy compound in the silicon etching solution is water, and particularly preferably ultrapure water in which the amount of metal impurities is reduced. The amount of impurities contained in water used as a raw material can be evaluated by electrical resistivity, and specifically, the electrical resistivity of the water used is preferably 0.1 MΩ·cm or more, more preferably 15 MΩ·cm or more, and particularly preferably 18 MΩ·cm or more. Such water having a small amount of impurities can be easily produced and obtained as ultrapure water for semiconductor manufacturing. Further, in a case of ultrapure water, impurities that do not influences (or have little influence on) the electrical resistivity are remarkably small, and suitability is high.

The mechanism that the generation of the pyramid-shaped hillocks surrounded by the 111 face on the silicon surface after the silicon etching can be prevented by the addition of the quaternary ammonium salt represented by the Formula (2) and the polyhydroxy compound even when the concentration of the quaternary ammonium hydroxide represented by the Formula (1) is low, is not necessarily clear. The present inventors consider as follows. It is considered that during the silicon etching using an alkali, the surface tends to be roughened when water in the etching solution contributes too much to the reaction. It is clear that the generation of the pyramid-shaped hillocks surrounded by the 111 face can be prevented usually by increasing the alkali concentration and reducing a water concentration. It is considered that by the addition of the polyhydroxy compound, the hydration due to the hydrogen bonding progresses and the number of the water molecules that can freely contribute to the reaction decreases, and therefore, even when the concentration of the quaternary ammonium hydroxide represented by the Formula (1) is low, the generation of the pyramid-shaped hillocks surrounded by the 111 face can be prevented. In addition, it is considered that when the ratio (OH/C) of the number of hydroxy groups to the number of carbon atoms in a molecule of the polyhydroxy compound is large, the amount of hydration of the hydroxy groups and water per unit mass is increased, and the generation of the pyramid-shaped hillocks surrounded by the (111) face can be efficiently prevented.

In order to improve smoothness of the silicon surface, it is important to bring an etching rate ratio (100/111) of a (100) face and a (111) face of silicon close to 1, and the smoothness can be improved by setting the etching rate ratio to 1.9 or less, and more preferably 1.8 or less.

In the first embodiment, the quaternary ammonium hydroxide represented by R¹¹R¹²R¹³R¹⁴N⁺·OH⁻ is used, and the quaternary ammonium salt represented by R²¹R²²R²³R²⁴N⁺·X⁻ is used. Therefore, the ammonium cation (R¹¹R¹²R¹³R¹⁴N⁺) and the OH⁻ are derived from the same raw material, the ammonium cation (R²¹R²²R²³R²⁴N⁺) and the X⁻ are derived from the same raw material, and other ionic components are not substantially contained. Therefore, the ammonium cation (R¹¹R¹²R¹³R¹⁴N⁺) and the OH⁻ have the same concentration, and the ammonium cation (R²¹R²²R²³R²⁴N⁺) and the X⁻ have the same concentration. A composition of the quaternary ammonium hydroxide represented by the Formula (1) and a composition of the quaternary ammonium salt represented by the Formula (2) in the silicon etching solution according to the present invention can be confirmed by analyzing and quantifying ionic components and the concentrations of the quaternary ammonium hydroxide represented by the Formula (1) and the quaternary ammonium salt represented by the Formula (2) an be obtained converting the concentrations of the ionic components in the solution to the concentrations of the compounds of Formulae (1) and (2). The quaternary ammonium cation can be measured by liquid chromatography or ion chromatography, the OH⁻ ion can be measured by neutralization titration, and the X⁻ ion can be measured by ion chromatography.

The silicon etching solution containing the components as described above is alkaline. In order to obtain a higher etching rate, a pH is preferably high, and specifically, the pH is preferably 10.0 or more, and more preferably 11.0 or more. An upper limit is generally 14.0 or less. The pH refers to a value measured at 25° C. by a glass electrode method.

The silicon etching solution according to the present invention is a uniform solution in which all blended components are dissolved. Further, in order to prevent contamination during the etching, the number of particles with 200 nm or more is preferably 100 particles/mL or less, and more preferably 50 particles/mL or less.

From a viewpoint of preventing contamination, the metal impurities are preferably as few as possible, and specifically, Ag, Al, Ba, Ca, Cd, Cr, Cu, Fe, K, Li, Mg, Mn, Na, Ni, Pb, and Zn are each preferably 1 ppb or less.

(Method for Producing Silicon Etching Solution According to First Embodiment)

A method for producing the silicon etching solution according to the first embodiment of the present invention is not particularly limited. The quaternary ammonium hydroxide represented by the Formula (1), the quaternary ammonium salt represented by the Formula (2), and the polyhydroxy compound may be mixed and dissolved in water so as to have a predetermined concentration. The quaternary ammonium hydroxide represented by the Formula (1) and the polyhydroxy compound may be used as they are, or may each be used as an aqueous solution. The quaternary ammonium salt represented by the Formula (2) may be used as it is, or may be used as an aqueous solution. Further, the silicon etching solution can also be produced by using a quaternary ammonium hydroxide represented by the following Formula (2-1) instead of the quaternary ammonium salt represented by the Formula (2) to obtain an aqueous solution containing the quaternary ammonium hydroxide represented by the Formula (1) and the quaternary ammonium hydroxide represented by the Formula (2-1), and then adding an appropriate amount of an acid represented by HX (X has the same definition as in the Formula (2)) to this aqueous solution.

R²¹R²²R²³R²⁴N⁺·OH⁻ (2-1)
(In the formula, R²¹, R²², R²³, and R²⁴ each have the same definition as in the Formula (2).)

(Silicon Etching Solution According to Second Embodiment)

Since the quaternary ammonium hydroxide and the quaternary ammonium salt are dissociated in the etching solution, when R¹¹R¹²R¹³R¹⁴N⁺X⁻ and R²¹R²²R²³R²⁴N⁺·OH⁻ in which anions in the raw materials of the first embodiment are exchanged each other, it is also possible to obtain a silicon etching solution having the same composition as a result.

A silicon etching solution according to a second embodiment of the present invention contains a quaternary ammonium cation represented by Formula (1′), a quaternary ammonium cation represented by Formula (2′), OH⁻, at least one anion selected from the group consisting of BF₄⁻, F⁻, Cl⁻, and Br⁻, a polyhydroxy compound having 2 to 12 carbon atoms and having two or more hydroxy groups in a molecule, and water.

R¹¹R¹²R¹³R¹⁴N⁺ (1′)

R²¹R²²R²³R²⁴N⁺ (2′)

In the Formula (1′), R¹¹, R¹², R¹³, and R¹⁴ are the same as those described for the above Formula (1), and preferable embodiments thereof are also the same. Examples of the quaternary ammonium cation represented by the Formula (1′) include a tetramethylammonium cation (TMA⁺), a tetraethylammonium cation (TEA+), an ethyltrimethylammonium cation (ETMA⁺), a tetrapropylammonium cation (TPA⁺), a tetrabutylammonium cation (TBA⁺), a trimethyl-2-hydroxyethylammonium cation, a dimethylbis(2-hydroxyethyl)ammonium cation, and a methyltris(2-hydroxyethyl)ammonium cation. Among these, TMA⁺, TEA⁺, ETMA⁺, TPA⁺, or TBA⁺ used in a silicon etching solution made of a quaternary ammonium hydroxide aqueous solution in the related art can be preferably used. In particular, TMA⁺, TEA⁺, ETMA⁺, or TPA⁺ is most preferably used because of having a high etching rate for silicon. The quaternary ammonium cation represented by the Formula (1′) may be used alone or in combination of two or more thereof.

In the Formula (2′), R²¹, R²², R²³, and R²⁴ are the same as those described for the Formula (2), and preferable embodiments thereof are also the same. Preferable examples of the quaternary ammonium cation represented by the Formula (2′) include a pentyltriethylammonium cation, a hexyltriethylammonium cation, an octyltrimethylammonium cation, a decyltrimethylammonium cation, a dodecyltrimethylammonium cation, and a tetradecyltrimethylammonium cation. Among these, an octyltrimethylammonium cation, a decyltrimethylammonium cation, or a dodecyltrimethylammonium cation can be preferably used. The quaternary ammonium cation represented by the Formula (2′) may be used alone or in combination of two or more thereof.

The polyhydroxy compound having 2 to 12 carbon atoms and having two or more hydroxy groups in a molecule is the same as that described in relation to the first embodiment, and preferable embodiments and blending amount thereof are also the same.

The at least one anion selected from the group consisting of BF₄⁻, F⁻, Cl⁻, and Br⁻ is preferably Cl⁻ or Br⁻, and more preferably Br⁻.

A concentration of the quaternary ammonium cation represented by the Formula (2′) is preferably 0.05 mol/L to 1.31 mol/L, more preferably 0.05 mol/L to 0.99 mol/L, and particularly preferably 0.05 mol/L to 0.50 mol/L. By setting the concentration of the quaternary ammonium cation represented by the Formula (2′) in this range, even when the concentration of the quaternary ammonium hydroxide is low, the silicon surface can be etched smoothly without any roughness. Specifically, surface roughness of a (100) face of silicon is reduced, and the pyramid-shaped hillocks surrounded by the (111) face are prevented, thereby enabling smooth etching.

A concentration of the quaternary ammonium cation represented by the Formula (1′) is not particularly different from that of a silicon etching solution in the related art, and the concentration is preferably in a range of 0.05 mol/L to 1.1 mol/L since a uniform etching solution having high solubility can be obtained and an excellent etching effect can be obtained. The concentration of the quaternary ammonium cation is more preferably in a range of 0.05 mol/L to 0.6 mol/L. The etching solution according to the present invention enables smooth etching having a high selectivity even when the concentration of the quaternary ammonium hydroxide is in a low range.

A concentration of OH⁻ is not particularly different from that of a silicon etching solution in the related art, and the concentration is preferably in a range of 0.05 mol/L to 1.1 mol/L since a uniform etching solution having high solubility can be obtained and an excellent etching effect can be obtained. The concentration of OH⁻ is more preferably in a range of 0.05 mol/L to 0.6 mol/L. The etching solution according to the present invention enables smooth etching having a high selectivity even when the concentration of the quaternary ammonium hydroxide is in a low range.

A concentration of the at least one anion selected from the group consisting of BF₄⁻, F⁻, Cl⁻, and Br is preferably 0.05 mol/L to 1.31 mol/L, more preferably 0.05 mol/L to 0.99 mol/L, and particularly preferably 0.05 mol/L to 0.50 mol/L.

Similar to the silicon etching solution according to the first embodiment, the silicon etching solution according to the second embodiment can also prevent the generation of the pyramid-shaped hillocks surrounded by the 111 face on the silicon surface after silicon etching. In order to improve smoothness of the silicon surface, it is important to bring an etching rate ratio (100/111) of a (100) face and a (111) face of silicon close to 1, and the smoothness can be improved by setting the etching rate ratio to 1.9 or less, and more preferably 1.8 or less. A preferable pH, a preferable amount of particles, and a preferable amount of metal impurities in the silicon etching solution according to the second embodiment are the same as those of the silicon etching solution according to the first embodiment.

(Method for Producing Silicon Etching Solution According to Second Embodiment)

A method for producing the silicon etching solution according to the second embodiment of the present invention is not particularly limited. The quaternary ammonium cation represented by the Formula (1′), the quaternary ammonium cation represented by the Formula (2), OH⁻, the at least one anion selected from the group consisting of BF₄⁻, F⁻, Cl⁻, and Br⁻, and the polyhydroxy compound may be mixed and dissolved in water so as to have a predetermined concentration.

In order to control the concentrations of the quaternary ammonium cation and the anion within predetermined ranges, the following quaternary ammonium compounds may be prepared and mixed in an appropriate amount.

R¹¹R¹²R¹³R¹⁴N⁺·OH⁻ (1)

R¹¹R¹²R¹³R¹⁴N⁺·X⁻ (1a)

R²¹R²²R²³R²⁴N⁺·X⁻ (2)

R²¹R²²R²³R²⁴N⁺·OH⁻ (2a)

In the above formulae, R¹¹, R¹², R¹³, R¹⁴, R²¹, R²², R²³, R²⁴, and X are the same as above.

In the production of the silicon etching solution according to the second embodiment of the present invention, as described in the first embodiment, filtration or bubbling may be performed, and the same container or apparatus can be used.

(Usage Embodiment of Silicon Etching Solution)

The silicon etching solution according to the present invention can be used for an etching treatment for silicon wafer and/or various silicon composite semiconductor devices including a silicon single crystal film, a polysilicon film, and an amorphous silicon film. Examples of the silicon single crystal film include a silicon single crystal film formed by epitaxial growth. Therefore, the silicon etching solution according to the present invention can be suitably used as an etching solution in a method for manufacturing a silicon device including a step of etching a silicon wafer, a silicon single crystal film, a polysilicon film, and an amorphous silicon film.

A substrate treatment method according to a first usage embodiment using the silicon etching solution according to the present invention includes a substrate holding step of holding a substrate in a horizontal posture, and a treatment solution supplying step of supplying the silicon etching solution according to the present invention to a main surface of the substrate while rotating the substrate around a vertical rotation axis passing through a central portion of the substrate.

A substrate treatment method according to a second usage embodiment using the silicon etching solution according to the present invention includes a substrate holding step of holding a plurality of substrates in an upright posture, and a step of immersing, in the upright posture, the substrates in the silicon etching solution according to the present invention stored in a treatment tank.

In a preferable usage embodiment of the present invention, the silicon etching solution is used for silicon device manufacturing including a step of supplying a silicon etching solution to etch a silicon film smoothly when etching a semiconductor wafer or a silicon wafer.

In consideration of a desired etching rate, shape and surface state of silicon after etching, productivity, and the like, a temperature of the silicon etching solution during the etching may be appropriately determined within a range of 20° C. to 95° C., and preferably a range of 35° C. to 90° C.

In wet etching for silicon, an etching target may be simply immersed in the silicon etching solution, and an electrochemical etching method can also be adopted to apply a constant potential to the etching target.

Examples of a target of the etching treatment in the present invention include a silicon single crystal, polysilicon, and amorphous silicon, and the target may contain a non-target silicon oxide film or silicon nitride film, silicon-germanium film, and various metal films, which are not targets of the etching treatment. Examples thereof include a structure in which a silicon oxide film, a silicon nitride film, or a silicon-germanium film, and a metal film are laminated on a silicon single crystal to create a pattern shape, a structure in which a silicon single crystal film or polysilicon film is further formed thereon, and a structure in which silicon is patterned.

### EXAMPLES

Hereinafter, the present invention is described in more detail with reference to Examples, but the present invention is not limited to these Examples.

### Example 1

A silicon etching solution having a composition shown in Table 1 was prepared using tetramethylammonium hydroxide (TMAH) as the quaternary ammonium hydroxide represented by the Formula (1), using dodecyltrimethylammonium bromide as the quaternary ammonium salt represented by the Formula (2), using ethylene glycol as the polyhydroxy compound, and using water as the balance. Ionic compositions (cations and anions) are shown together.

<Evaluation for Surface Roughness on Silicon Single Crystal Substrate>

A silicon single crystal substrate (100 face) having a size of 2×2 cm was immersed in the silicon etching solution heated to 40° C. for 120 minutes, and an etching rate for a silicon single crystal at this temperature was measured. The target silicon single crystal substrate is obtained by removing a natural oxide film with a chemical solution. The etching rate (R₁₀₀) was obtained by measuring weights of the silicon single crystal substrate before and after the etching the silicon single crystal substrate (100 face), calculating an etching amount of the silicon single crystal substrate from a difference of the weights before and after the treatment, and dividing the etching amount by an etching time. Similarly, a silicon single crystal substrate (111 face) having a size of 2×2 cm was immersed for 120 minutes, an etching rate (R₁₁₁) for a silicon single crystal at this temperature was measured, and an etching rate ratio (R₁₀₀/R₁₁₁) to the silicon single crystal substrate (100 face) was obtained.

A surface state of the silicon single crystal substrate (100 face) after etching about 1 μm was observed using a field-emission scanning electron microscope (FE-SEM), and evaluated according to the following criteria. Results are shown in Table 1.

<FE-SEM Observation Results of Silicon Single Crystal Substrate (100 Face)>

Measurement 1: any three locations were selected at an observation magnification of 20,000 times, 50 μm square was observed, and the presence or absence of hillocks was confirmed.
5: No hillocks are observed in the observation field of view.
3: Minute hillocks are observed in the observation field of view.
0: A large number of hillocks are observed in the observation field of view.

Measurement 2: any three locations were selected at an observation magnification of 100,000 times, 1 μm square was observed, and the number of protrusions was determined as hillocks.

<Evaluation for Selection Ratio of Silicon Single Crystal to Silicon Oxide Film and Silicon Nitride Film>

A silicon oxide film and a silicon nitride film were immersed in the silicon etching solution heated to 40° C. for 10 minutes, and etching rates of the silicon oxide film and the silicon nitride film were measured at this temperature. The etching rates were obtained by measuring film thicknesses before and after the etching of the silicon oxide film and the silicon nitride film using a spectroscopic ellipsometer, calculating etching amounts of the silicon oxide film and the silicon nitride film from differences of the film thicknesses before and after the treatment, and dividing each of the etching amounts by an etching time. Next, etching rate ratios (R₁₀₀/silicon oxide film) and (R₁₀₀/silicon nitride film) to the silicon single crystal substrate (100 face) were calculated, and evaluated according to the following criteria. Results are shown in Table 1.

<Evaluation Criteria of Selection Ratio of Silicon Single Crystal to Silicon Oxide Film and Silicon Nitride Film>

Selection ratio of silicon single crystal to silicon oxide film (Si (100 face)/SiO₂)
A: 1,000 or more, B: 700 or more and less than 1,000, C: 500 or more and less than 700, D: less than 500

Selection ratio of silicon single crystal to silicon nitride film (Si (100 face)/SiN)
A: 1,000 or more, B: 700 or more and less than 1,000, C: 500 or more and less than 700, D: less than 500
B and thereabove showed good selectivity.

### Examples 2 to 11, Reference Example 1, and Comparative Examples 1 to 24

An evaluation was performed in the same manner as in Example 1 except that a silicon etching solution having a composition shown in Table 1 and Table 2 was used as the silicon etching solution. Results are shown in Table 1 and Table 2.

Abbreviations in the Tables are as Follows.
TMAH: tetramethylammonium hydroxide
TEAH: tetraethylammonium hydroxide
ETMAH: ethyltrimethylammonium hydroxide
TPAH: tetrapropylammonium hydroxide
TBAH: tetrabutylammonium hydroxide
TMA⁺: tetramethylammonium cation
TEA⁺: tetraethylammonium cation
ETMA⁺: ethyltrimethylammonium cation
TPA⁺: tetrapropylammonium cation
TBA⁺: tetrabutylammonium cation

TABLE 1

| | Silicon etching solution (preparation composition) | | | | | | | | |
|---|---|---|---|---|---|---|---|---|---|
| | Quaternary | | | | Quaternary | | | | |
| | ammonium | | | | ammonium | | Silicon etching solution (ionic composition) | | |
| | hydroxide | | | | salt | | Quaternary | | |
| | (compound | | | | (compound | | ammonium | | |
| | represented | | | | represented | | cation of | | OH⁻ |
| | by Formula | Content | Polyhydroxy | Content | by Formula | Content | Formula | Content | content |
| | (1)) | (mol/L) | compound | (mass %) | (2)) | (mass %) | (1′) | (mol/L) | (mol/L) |
| Exam- | TMAH | 0.26 | Ethylene glycol | 40 | Dodecyltrimethyl- | 3 | TMA⁺ | 0.26 | 0.26 |
| ple 1 | | | | | ammonium | | | | |
| | | | | | bromide | | | | |
| Exam- | TMAH | 0.26 | Ethylene glycol | 60 | Dodecyltrimethyl- | 3 | TMA⁺ | 0.26 | 0.26 |
| ple 2 | | | | | ammonium | | | | |
| | | | | | bromide | | | | |
| Exam- | ETMAH | 0.26 | Glycerin | 40 | Decyltrimethyl- | 5 | ETMA⁺ | 0.26 | 0.26 |
| ple 3 | | | | | ammonium | | | | |
| | | | | | bromide | | | | |
| Exam- | TPAH | 0.26 | Ethylene glycol | 20 | Decyltrimethyl- | 3 | TPA⁺ | 0.26 | 0.26 |
| ple 4 | | | | | ammonium | | | | |
| | | | | | bromide | | | | |
| Exam- | TPAH | 0.26 | Ethylene glycol | 20 | Octyltrimethyl- | 25 | TPA⁺ | 0.26 | 0.26 |
| ple 5 | | | | | ammonium | | | | |
| | | | | | bromide | | | | |
| Exam- | TPAH | 0.26 | Ethylene glycol | 50 | Dodecyltrimethyl- | 3 | TPA⁺ | 0.26 | 0.26 |
| ple 6 | | | Diglycerin | 10 | ammonium | | | | |
| | | | | | bromide | | | | |
| Exam- | TPAH | 0.26 | Ethylene glycol | 30 | Dodecyltrimethyl- | 1.5 | TPA⁺ | 0.26 | 0.26 |
| ple 7 | | | Glycerin | 30 | ammonium | | | | |
| | | | | | bromide | | | | |
| Exam- | TMAH | 0.26 | Glycerin | 40 | Octyltrimethyl- | 10 | TMA⁺ | 0.26 | 0.26 |
| ple 8 | | | | | ammonium | | | | |
| | | | | | bromide | | | | |
| Exam- | TPAH | 0.26 | Diglycerin | 20 | Dodecyltrimethyl- | 3 | TPA⁺ | 0.26 | 0.26 |
| ple 9 | | | | | ammonium | | | | |
| | | | | | bromide | | | | |
| Exam- | TPAH | 0.26 | Xylitol | 20 | Dodecyltrimethyl- | 3 | TPA⁺ | 0.26 | 0.26 |
| ple 10 | | | | | ammonium | | | | |
| | | | | | bromide | | | | |
| Exam- | TBAH | 0.26 | Ethylene glycol | 20 | Decyltrimethyl- | 3 | TBA⁺ | 0.26 | 0.26 |
| ple 11 | | | | | ammonium | | | | |
| | | | | | bromide | | | | |

| | Silicon etching solution (ionic composition) | | | | | | Si | | |
|---|---|---|---|---|---|---|---|---|---|
| | Quaternary | | | | | | (100/111) | | |
| | ammonium | | Anion | | FE-SEM evaluation | | etching | | |
| | cation of | | selected | | for surface state | | selection | Selection ratio | |
| | Formula | Content | from BF₄⁻, F⁻, | Content | Measure- | Measure- | ratio | evaluation (A to E) | |
| | (2′) | (mol/L) | Cl⁻, Br⁻ | (mol/L) | ment 1 | ment 2 | (R₁₀₀/R₁₁₁) | Si/SiO₂ | Si/SiN |
| Exam- | Dodecyltrimethyl- | 0.10 | Br⁺ | 0.10 | 5 | 80 | 1.6 | A | A |
| ple 1 | ammonium | | | | | | | | |
| | cation | | | | | | | | |
| Exam- | Dodecyltrimethyl- | 0.10 | Br⁺ | 0.10 | 5 | 70 | 1.5 | A | A |
| ple 2 | ammonium | | | | | | | | |
| | cation | | | | | | | | |
| Exam- | Decyltrimethyl- | 0.18 | Br⁺ | 0.18 | 5 | 60 | 1.5 | A | A |
| ple 3 | ammonium | | | | | | | | |
| | cation | | | | | | | | |
| Exam- | Decyltrimethyl- | 0.11 | Br⁺ | 0.11 | 5 | 40 | 1.5 | A | A |
| ple 4 | ammonium | | | | | | | | |
| | cation | | | | | | | | |
| Exam- | Octyltrimethyl- | 0.99 | Br⁺ | 0.99 | 5 | 30 | 1.4 | A | A |
| ple 5 | ammonium | | | | | | | | |
| | cation | | | | | | | | |
| Exam- | Dodecyltrimethyl- | 0.10 | Br⁺ | 0.10 | 5 | 20 | 1.3 | A | A |
| ple 6 | ammonium | | | | | | | | |
| | cation | | | | | | | | |
| Exam- | Dodecyltrimethyl- | 0.05 | Br⁺ | 0.05 | 5 | 30 | 1.4 | A | A |
| ple 7 | ammonium | | | | | | | | |
| | cation | | | | | | | | |
| Exam- | Octyltrimethyl- | 0.40 | Br⁺ | 0.40 | 5 | 50 | 1.5 | A | A |
| ple 8 | ammonium | | | | | | | | |
| | cation | | | | | | | | |
| Exam- | Dodecyltrimethyl- | 0.10 | Br⁺ | 0.10 | 5 | 40 | 1.5 | A | A |
| ple 9 | ammonium | | | | | | | | |
| | cation | | | | | | | | |
| Exam- | Dodecyltrimethyl- | 0.10 | Br⁺ | 0.10 | 5 | 40 | 1.5 | A | A |
| ple 10 | ammonium | | | | | | | | |
| | cation | | | | | | | | |
| Exam- | Decyltrimethyl- | 0.11 | Br⁺ | 0.11 | 5 | 40 | 1.5 | A | A |
| ple 11 | ammonium | | | | | | | | |
| | cation | | | | | | | | |

TABLE 2

| | Silicon etching solution(preparation composition) | | | | | | | | |
|---|---|---|---|---|---|---|---|---|---|
| | Quaternary | | | | Quaternary | | | | |
| | ammonium | | | | ammonium | | Silicon etching solution(ionic composition) | | |
| | hydroxide | | | | salt | | Quaternary | | |
| | (compound | | | | (compound | | ammonium | | |
| | represented | | Polyhy- | | represented | | cation of | | OH⁻ |
| | by Formula | Content | droxy | Content | by Formula | Content | Formula | Content | content |
| | (1)) | (mol/L) | compound | (mass %) | (2)) | (mass %) | (1′) | (mol/L) | (mol/L) |
| Refer- | TPAH | 2.08 | — | — | — | — | TPA⁺ | 2.08 | 2.08 |
| ence | | | | | | | | | |
| Exam- | | | | | | | | | |
| ple 1 | | | | | | | | | |
| Compar- | TMAH | 0.26 | Ethylene glycol | 40 | — | — | TMA⁺ | 0.26 | 0.26 |
| ative | | | | | | | | | |
| Exam- | | | | | | | | | |
| ple 1 | | | | | | | | | |
| Compar- | TMAH | 0.26 | Ethylene glycol | 60 | — | — | TMA⁺ | 0.26 | 0.26 |
| ative | | | | | | | | | |
| Exam- | | | | | | | | | |
| ple 2 | | | | | | | | | |
| Compar- | TMAH | 0.26 | Ethylene glycol | 60 | Dodecyl- | 0.2 | TMA⁺ | 0.26 | 0.26 |
| ative | | | | | trimethyl- | | | | |
| Exam- | | | | | ammonium | | | | |
| ple 3 | | | | | bromide | | | | |
| Compar- | ETMAH | 0.26 | Glycerin | 40 | — | — | ETMA⁺ | 0.26 | 0.26 |
| ative | | | | | | | | | |
| Exam- | | | | | | | | | |
| ple 4 | | | | | | | | | |
| Compar- | TPAH | 0.26 | Ethylene glycol | 20 | — | — | TPA⁺ | 0.26 | 0.26 |
| ative | | | | | | | | | |
| Exam- | | | | | | | | | |
| ple 5 | | | | | | | | | |
| Compar- | TPAH | 0.26 | Ethylene glycol | 50 | — | — | TPA⁺ | 0.26 | 0.26 |
| ative | | | Diglycerin | 10 | | | | | |
| Exam- | | | | | | | | | |
| ple 6 | | | | | | | | | |
| Compar- | TPAH | 0.26 | Ethylene glycol | 30 | | | TPA⁺ | 0.26 | 0.26 |
| ative | | | Glycerin | 30 | | | | | |
| Exam- | | | | | | | | | |
| ple 7 | | | | | | | | | |
| Compar- | TPAH | 0.26 | Ethylene glycol | 30 | Dodecyl- | 0.2 | TPA⁺ | 0.26 | 0.26 |
| ative | | | Glycerin | 30 | trimethyl- | | | | |
| Exam- | | | | | ammonium | | | | |
| ple 8 | | | | | bromide | | | | |
| Compar- | TMAH | 0.26 | — | — | — | — | TMA⁺ | 0.26 | 0.26 |
| ative | | | | | | | | | |
| Exam- | | | | | | | | | |
| ple 9 | | | | | | | | | |
| Compar- | TEAH | 0.26 | — | — | — | — | TEA⁺ | 0.26 | 0.26 |
| ative | | | | | | | | | |
| Exam- | | | | | | | | | |
| ple 10 | | | | | | | | | |
| Compar- | TPAH | 0.26 | — | — | — | — | TPA⁺ | 0.26 | 0.26 |
| ative | | | | | | | | | |
| Exam- | | | | | | | | | |
| ple 11 | | | | | | | | | |
| Compar- | TBAH | 0.26 | — | — | — | — | TBA⁺ | 0.26 | 0.26 |
| ative | | | | | | | | | |
| Exam- | | | | | | | | | |
| ple 12 | | | | | | | | | |
| Compar- | TMAH | 0.26 | — | — | Octyl- | 5 | TMA⁺ | 0.26 | 0.26 |
| ative | | | | | trimethyl- | | | | |
| Exam- | | | | | ammonium | | | | |
| ple 13 | | | | | bromide | | | | |
| Compar- | KOH | 3.08 | — | — | — | — | K⁺ | 3.08 | 3.08 |
| ative | | | | | | | | | |
| Exam- | | | | | | | | | |
| ple 14 | | | | | | | | | |
| Compar- | TMAH | 0.26 | Ethylene glycol | 70 | — | — | TMA⁺ | 0.26 | 0.26 |
| ative | | | | | | | | | |
| Exam- | | | | | | | | | |
| ple 15 | | | | | | | | | |
| Compar- | TMAH | 0.26 | Glycerin | 60 | — | — | TMA⁺ | 0.26 | 0.26 |
| ative | | | | | | | | | |
| Exam- | | | | | | | | | |
| ple 16 | | | | | | | | | |
| Compar- | TMAH | 0.26 | Ethylene glycol | 30 | — | — | TMA⁺ | 0.26 | 0.26 |
| ative | | | Glycerin | 30 | | | | | |
| Exam- | | | | | | | | | |
| ple 17 | | | | | | | | | |
| Compar- | ETMAH | 0.26 | Glycerin | 60 | — | — | ETMA⁺ | 0.26 | 0.26 |
| ative | | | | | | | | | |
| Exam- | | | | | | | | | |
| ple 18 | | | | | | | | | |
| Compar- | TPAH | 0.26 | Ethylene glycol | 10 | — | — | TPA⁺ | 0.26 | 0.26 |
| ative | | | | | | | | | |
| Exam- | | | | | | | | | |
| ple 19 | | | | | | | | | |
| Compar- | TPAH | 0.26 | Ethylene glycol | 60 | — | — | TPA⁺ | 0.26 | 0.26 |
| ative | | | | | | | | | |
| Exam- | | | | | | | | | |
| ple 20 | | | | | | | | | |
| Compar- | TPAH | 0.49 | Ethylene glycol | 60 | — | — | TPA⁺ | 0.49 | 0.49 |
| ative | | | | | | | | | |
| Exam- | | | | | | | | | |
| ple 21 | | | | | | | | | |
| Compar- | TPAH | 0.26 | Xylibl | 60 | — | — | TPA⁺ | 0.26 | 0.26 |
| ative | | | | | | | | | |
| Exam- | | | | | | | | | |
| ple 22 | | | | | | | | | |
| Compar- | TBAH | 0.26 | Pentaerythritol | 3 | — | — | TBA⁺ | 0.26 | 0.26 |
| ative | | | | | | | | | |
| Exam- | | | | | | | | | |
| ple 23 | | | | | | | | | |
| Compar- | TBAH | 0.26 | Ethylene glycol | 60 | — | — | TBA⁺ | 0.26 | 0.26 |
| ative | | | | | | | | | |
| Exam- | | | | | | | | | |
| ple 24 | | | | | | | | | |

| | Silicon etching solution(ionic composition) | | | | | | Si | | |
|---|---|---|---|---|---|---|---|---|---|
| | Quaternary | | Anion | | | | (100/111) | | |
| | ammonium | | selected | | FE-SEM evaluation | | etching | Selection ratio | |
| | cation of | | from | | for surface state | | selection | evaluation (A to E) | |
| | Formula | Content | BF₄⁻, F⁻, | Content | Measure- | Measure- | ratio | Si/ | Si/ |
| | (2′) | (mol/L) | Cl⁻, Br⁻ | (mol/L) | ment 1 | ment2 | (R₁₀₀/R₁₁₁) | SiO₂ | SiN |
| Refer- | — | — | — | — | 5 | 160 | 1.9 | A | A |
| ence | | | | | | | | | |
| Exam- | | | | | | | | | |
| ple 1 | | | | | | | | | |
| Compar- | — | — | — | — | 5 | 150 | 1.8 | A | A |
| ative | | | | | | | | | |
| Exam- | | | | | | | | | |
| ple 1 | | | | | | | | | |
| Compar- | — | — | — | — | 5 | 120 | 1.7 | A | A |
| ative | | | | | | | | | |
| Exam- | | | | | | | | | |
| ple 2 | | | | | | | | | |
| Compar- | Dodecyl- | 0.01 | Br⁺ | 0.01 | 5 | 130 | 1.7 | A | A |
| ative | trimethyl- | | | | | | | | |
| Exam- | ammonium | | | | | | | | |
| ple 3 | cation | | | | | | | | |
| Compar- | — | — | — | — | 5 | 150 | 1.8 | A | A |
| ative | | | | | | | | | |
| Exam- | | | | | | | | | |
| ple 4 | | | | | | | | | |
| Compar- | — | — | — | — | 5 | 120 | 1.8 | A | A |
| ative | | | | | | | | | |
| Exam- | | | | | | | | | |
| ple 5 | | | | | | | | | |
| Compar- | — | — | — | — | 5 | 30 | 1.4 | A | A |
| ative | | | | | | | | | |
| Exam- | | | | | | | | | |
| ple 6 | | | | | | | | | |
| Compar- | — | — | — | — | 5 | 40 | 1.5 | A | A |
| ative | | | | | | | | | |
| Exam- | | | | | | | | | |
| ple 7 | | | | | | | | | |
| Compar- | Dodecyl- | 0.01 | Br⁺ | 0.01 | 5 | 40 | 1.5 | A | A |
| ative | trimethyl- | | | | | | | | |
| Exam- | ammonium | | | | | | | | |
| ple 8 | cation | | | | | | | | |
| Compar- | — | — | — | — | 0 | 500 or | 3.6 | A | A |
| ative | | | | | | more | | | |
| Exam- | | | | | | | | | |
| ple 9 | | | | | | | | | |
| Compar- | — | — | — | — | 0 | 500 or | 4.0 | A | A |
| ative | | | | | | more | | | |
| Exam- | | | | | | | | | |
| ple 10 | | | | | | | | | |
| Compar- | — | — | — | — | 3 | 500 or | 2.4 | A | A |
| ative | | | | | | more | | | |
| Exam- | | | | | | | | | |
| ple 11 | | | | | | | | | |
| Compar- | — | — | — | — | 3 | 200 | 2.0 | A | A |
| ative | | | | | | | | | |
| Exam- | | | | | | | | | |
| ple 12 | | | | | | | | | |
| Compar- | Octyl- | 0.20 | Br⁺ | 0.20 | 3 | 500 or | 2.8 | A | A |
| ative | trimethyl- | | | | | more | | | |
| Exam- | ammonium | | | | | | | | |
| ple 13 | cation | | | | | | | | |
| Compar- | — | — | — | — | 0 | 500 or | 7.0 | D | D |
| ative | | | | | | more | | | |
| Exam- | | | | | | | | | |
| ple 14 | | | | | | | | | |
| Compar- | — | — | — | — | 5 | 90 | 1.6 | A | A |
| ative | | | | | | | | | |
| Exam- | | | | | | | | | |
| ple 15 | | | | | | | | | |
| Compar- | — | — | — | — | 5 | 120 | 1.7 | A | A |
| ative | | | | | | | | | |
| Exam- | | | | | | | | | |
| ple 16 | | | | | | | | | |
| Compar- | — | — | — | — | 5 | 110 | 1.7 | A | A |
| ative | | | | | | | | | |
| Exam- | | | | | | | | | |
| ple 17 | | | | | | | | | |
| Compar- | — | — | — | — | 5 | 90 | 1.6 | A | A |
| ative | | | | | | | | | |
| Exam- | | | | | | | | | |
| ple 18 | | | | | | | | | |
| Compar- | — | — | — | — | 5 | 160 | 1.9 | A | A |
| ative | | | | | | | | | |
| Exam- | | | | | | | | | |
| ple 19 | | | | | | | | | |
| Compar- | — | — | — | — | 5 | 40 | 1.5 | A | A |
| ative | | | | | | | | | |
| Exam- | | | | | | | | | |
| ple 20 | | | | | | | | | |
| Compar- | — | — | — | — | 5 | 40 | 1.5 | A | A |
| ative | | | | | | | | | |
| Exam- | | | | | | | | | |
| ple 21 | | | | | | | | | |
| Compar- | — | — | — | — | 5 | 50 | 1.5 | A | A |
| ative | | | | | | | | | |
| Exam- | | | | | | | | | |
| ple 22 | | | | | | | | | |
| Compar- | — | — | — | — | 5 | 170 | 1.9 | A | A |
| ative | | | | | | | | | |
| Exam- | | | | | | | | | |
| ple 23 | | | | | | | | | |
| Compar- | — | — | — | — | 5 | 40 | 1.5 | A | A |
| ative | | | | | | | | | |
| Exam- | | | | | | | | | |
| ple 24 | | | | | | | | | |

1. A silicon etching solution comprising:
a quaternary ammonium hydroxide represented by the following Formula (1):
R¹¹R¹²R¹³R¹⁴N⁺·OH⁻ (1)
(in the formula, R¹¹, R¹², R¹³, and R¹⁴ are each independently an aryl group, a benzyl group, or an alkyl group having 1 to 4 carbon atoms, and the alkyl group, the aryl group, or the benzyl group may have a hydroxy group);
a quaternary ammonium salt represented by the following Formula (2) and having 11 to 20 carbon atoms in total:
R²¹R²²R²³R²⁴N⁺·X⁻ (2)
(in the formula, one of R²¹, R²², R²³, and R²⁴ is an alkyl group having 16 or less carbon atoms, which may have a substituent, each of the remaining three is an alkyl group having 1 or 2 carbon atoms, the alkyl group having 16 or less carbon atoms and the alkyl group having 1 or 2 carbon atoms may have a hydroxy group, and X is at least one selected from the group consisting of BF₄, a fluorine atom, a chlorine atom, and a bromine atom);
a polyhydroxy compound having 2 to 12 carbon atoms and having two or more hydroxy groups in a molecule; and
water, wherein
a concentration of the quaternary ammonium salt represented by the Formula (2) is 1.5 mass % to 50 mass %.

2. The silicon etching solution according to claim 1, wherein
a concentration of the quaternary ammonium hydroxide represented by the Formula (1) is 0.05 mol/L to 1.1 mol/L, and
a concentration of the polyhydroxy compound having 2 to 12 carbon atoms and having two or more hydroxy groups in a molecule is 10 mass % to 80 mass %.

3. A silicon etching solution comprising:
a quaternary ammonium cation represented by the following Formula (1′):
R¹¹R¹²R¹³R¹⁴N⁺ (1′)
(in the formula, R¹¹, R¹², R¹³, and R¹⁴ are each independently an aryl group, a benzyl group, or an alkyl group having 1 to 4 carbon atoms, and the alkyl group, the aryl group, or the benzyl group may have a hydroxy group);
a quaternary ammonium cation represented by the following Formula (2′) and having 11 to 20 carbon atoms in total:
R²¹R²²R²³R²⁴N⁺ (2′)
(in the formula, one of R²¹, R²², R²³, and R²⁴ is an alkyl group having 16 or less carbon atoms, which may have a substituent, each of the remaining three is an alkyl group having 1 or 2 carbon atoms, and the alkyl group having 16 or less carbon atoms and the alkyl group having 1 or 2 carbon atoms may have a hydroxy group);
OH⁻;
at least one anion selected from the group consisting of BF₄⁻, F⁻, Cl⁻, and Br⁻;
a polyhydroxy compound having 2 to 12 carbon atoms and having two or more hydroxy groups in a molecule; and
water, wherein
a content of the quaternary ammonium cation represented by the Formula (2′) is 0.05 mol/L to 1.31 mol/L, and the silicon etching solution is alkaline.

4. The silicon etching solution according to claim 3, wherein
a concentration of the quaternary ammonium cation represented by the Formula (1′) is 0.05 mol/L to 1.1 mol/L,
a concentration of OH⁻ is 0.05 mol/L to 1.1 mol/L,
a concentration of the at least one anion selected from the group consisting of BF₄, F, Cl⁻, and Br⁻ is 0.05 mol/L to 1.31 mol/L, and
a concentration of the polyhydroxy compound having 2 to 12 carbon atoms and having two or more hydroxy groups in a molecule is 10 mass % to 80 mass %.

5. A silicon wafer and/or substrate treatment method, comprising:
etching a silicon wafer or etching a substrate including at least one selected from the group consisting of a silicon single crystal film, a polysilicon film, and an amorphous silicon film by using the silicon etching solution according to claim 1.

6. A method for manufacturing a silicon device, comprising:
etching at least one selected from the group consisting of a silicon wafer, a silicon single crystal film, a polysilicon film, and an amorphous silicon film, wherein
the etching is performed using the silicon etching solution according to claim 1.

7. A silicon wafer and/or substrate treatment method, comprising:
etching a silicon wafer or etching a substrate including at least one selected from the group consisting of a silicon single crystal film, a polysilicon film, and an amorphous silicon film by using the silicon etching solution according to claim 2.

8. A silicon wafer and/or substrate treatment method, comprising:
etching a silicon wafer or etching a substrate including at least one selected from the group consisting of a silicon single crystal film, a polysilicon film, and an amorphous silicon film by using the silicon etching solution according to claim 3.

9. A silicon wafer and/or substrate treatment method, comprising:
etching a silicon wafer or etching a substrate including at least one selected from the group consisting of a silicon single crystal film, a polysilicon film, and an amorphous silicon film by using the silicon etching solution according to claim 4.

10. A method for manufacturing a silicon device, comprising:
etching at least one selected from the group consisting of a silicon wafer, a silicon single crystal film, a polysilicon film, and an amorphous silicon film, wherein
the etching is performed using the silicon etching solution according to claim 2.

11. A method for manufacturing a silicon device, comprising:
etching at least one selected from the group consisting of a silicon wafer, a silicon single crystal film, a polysilicon film, and an amorphous silicon film, wherein
the etching is performed using the silicon etching solution according to claim 3.

12. A method for manufacturing a silicon device, comprising:
etching at least one selected from the group consisting of a silicon wafer, a silicon single crystal film, a polysilicon film, and an amorphous silicon film, wherein
the etching is performed using the silicon etching solution according to claim 4.
